(19) United States
(12) Patent Application Publication
(10) Pub. No.: US 2025/0093561 A1
(43) Pub. Date: Mar. 20, 2025

(54) BLUE FILTERS COMPRISING SEMICONDUCTOR NANOPARTICLES AND USES THEREOF

(71) Applicant: NEXDOT, Romainville (FR)

(72) Inventors: Benoît DUBERTRET, Romainville (FR); Guillaume NAUDIN, Romainville (FR); Michele D'AMICO, Romainville (FR); Wilfried SOLO-OJO, Romainville (FR); Marc POUSTHOMIS, Romainville (FR); Antoine AMESTOY, Romainville (FR); Edgar CAO, Romainville (FR)

(73) Assignee: NEXDOT, Romainville (FR)

(21) Appl. No.: 18/550,774

(22) PCT Filed: Feb. 19, 2021
(86) PCT No.: PCT/EP2021/054210

§ 371 Date: Sep. 15, 2023

(30) Foreign Application Priority Data
Feb. 21, 2020 (EP) 20305171.9

(51) Int. Cl. G02B 5/20; H10H 29/85

(52) U.S. Cl. CPC G02B 5/206; G02B 5/207; H10H 29/8517; G02B 2207/101

(57) ABSTRACT

A light filtering material including at least one matrix material; and semi-conductive nanoparticles which are dispersed in the matrix material. The light filtering material has: a local maximum absorbance of highest wavelength in the range from 350 to 500 nm, the local maximum has an absorbance value Aₘₐₓ for a wavelength λₘₐₓ; a value of 0.9Aₘₐₓ for a wavelength λ_{0.9}, λ_{0.9} being greater than λₘₐₓ; a value of 0.5Aₘₐₓ for a wavelength λ_{0.5}, λ_{0.5} being greater than λ_{0.9}; and |λ_{0.5}−λ_{0.9}| is less than 15 nm.

### FIELD OF INVENTION

The present invention relates to the field of light filtering materials, in particular blue filters for the manufacture of various articles such as displays, glass containers and optical articles, especially ophthalmic lenses. The light filtering material comprises semi-conductive nanoparticles with specific light absorbing properties. The disclosure also relates to the use of said light filtering material in various applications.

### BACKGROUND OF INVENTION

It is common knowledge that UV light and blue light, also known as high-energy visible (HEV) light, corresponding to visible light in the blue-violet band between 380 and 500 nm, can have deleterious effects on humans or their environment.

For example, prolonged exposure to blue light emitted from digital devices such as television, laptops, tablets and smartphones and fluorescent and LED lighting is harmful to the human eye as blue light is able to reach the retina. Some specific ranges of blue light have been shown to cause photoretinitis; digital eyestrain, or computer vision syndrome which includes blurry vision, difficulty focusing, dry and irritated eyes, headaches, neck and back pain; disruption of the circadian rhythm; decreased melanin production; age-related macular degeneration; glaucoma; retinal degenerative diseases; breast and prostate cancer; diabetes; heart disease; obesity and depression. Blue light in the range from about 420 to 450 nm is believed to be especially harmful.

To protect the human eye from UV light and blue light, several solutions have been developed such as incorporating light-absorbers in ophthalmic lenses. Usually, several additives are used, each absorber being efficient over a limited wavelength range.

However, the incorporation of light-absorbers in ophthalmic lenses by conventional methods (impregnation of a polymerized lens in a bath containing a light-absorber in EP1085349, coating of a substance capable of absorbing light rays onto the surface of ophthalmic lenses in U.S. Pat. No. 5,949,518, incorporation of a light-absorber in the bulk liquid formulation) results in a coating that may weaken the mechanical properties of the lens, and/or in undesirable yellowing due to degradation of the light-absorber during polymerization and/or upon ageing.

Another solution would be to incorporate a light absorber directly in the digital device. However, conventional methods have the drawback to lead to a yellowing effect.

Yellowing of the lens or the screen is undesirable for cosmetic reasons and because it can affect the colour perception of the user and eventually lower the transmittance of lenses or screen.

There is thus a need for a light filtering material for the manufacture of ophthalmic lenses or digital devices, the light filtering material having a well-defined absorbance spectrum able to protect eye against high energy radiations and optimize color perception.

UV light and blue light can also affect the flavour of food products upon exposition to light. In the brewing and wine industry it has been known for centuries that light, and in particular sunlight, may negatively affect the flavour of many types of beers or wines. The flavour resulting from the light exposure is therefore commonly referred to as “lightstruck” flavour and considered by most consumers to be highly repulsive.

Although exact origin of the lightstruck flavour in real beverages is not totally understood, it is generally agreed that Riboflavin—vitamin B2—and its spectroscopically equivalent derivates, are prone to reduction upon photoactivation, accepting hydrogen ions and one or two electrons, thus initiating degradation reactions of other compounds, leading eventually to thiol compounds strong having flavour. In particular, 3-methyl-2-butene-1-thiol (3-MBT) is believed to be formed by the reaction between light excited Riboflavin and iso-alpha-acids. The range of wavelength where photoactivation is the more efficient is in the blue part of light spectrum, around 440-450 nm.

To avoid photoactivation of Riboflavin, several solutions have been developed. Most common solution is the use of coloured glass containers, usually green or brown, with a very strong filtering of blue component of light-natural or artificial. This use of coloured glass containers is a drawback as the customer cannot see the beverage aspect and assess its quality.

There is thus a need for a light filtering material for the manufacture of glass containers allowing for efficient filtration of blue light in the range of wavelength around 440-450 nm while keeping a very low colour. Such an filter allows to use white glass containers without the risk of lightstruck flavour generation. White glass containers allow for a better presentation of the liquid contained therein and are more adapted to high end markets.

The Applicant has found that these needs could be met with semi-conductive nanoparticles dispersed in a matrix material.

### SUMMARY

The present invention relates to a light filtering material comprising:
a. at least one matrix material; and
b. semi-conductive nanoparticles which are dispersed in said matrix material; and
wherein said light filtering material absorbs light, and
wherein absorbance of said light filtering material has
   a local maximum absorbance of highest wavelength in the range from 350 to 500 nm, said local maximum having an absorbance value Aₘₐₓ for a wavelength λₘₐₓ,
   a value of 0.9Aₘₐₓ for a wavelength λ_{0.9}, λ_{0.9} being greater than λₘₐₓ;
   a value of 0.5Aₘₐₓ for a wavelength λ_{0.5}, λ_{0.5} being greater than λ_{0.9}; and
wherein |λ_{0.5}-λ_{0.9}| is less than 15 nm.

In one embodiment, absorbance of said light filtering material has a value of 0.1Aₘₐₓ for a wavelength λ_{0.1}, λ_{0.1} being greater than λ_{0.9}; and wherein |λ_{0.1}−λ_{0.9}| is less than 30 nm.

In one embodiment, the semi-conductive nanoparticles comprise a material of formula MₓQ_{y}E_{z}A_{w} (I), wherein M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof; E is selected from the group consisting of O, S, Se, Te, C, N, P, As, Sb, F, Cl, Br, I, or a mixture thereof; A is selected from the group consisting of O, S, Se, Te, C, N, P, As, Sb, F, Cl, Br, I, or a mixture thereof; and x, y, z and w are independently a decimal number from 0 to 5; x, y, z and w are not simultaneously equal to 0; x and y are not simultaneously equal to 0; z and w may not be simultaneously equal to 0.

In one embodiment, the semi-conductive nanoparticles are nanospheres, nanoplates or nanorods. In one embodiment, the semi-conductive nanoparticles are homostructures. In one embodiment, the semi-conductive nanoparticles are core/shell nanoparticles or core/crown nanoparticles, the core being a different material from the shell or crown.

In one embodiment, the amount of semi-conductive nanoparticles in the light filtering is from 10 ppm to 10 wt %, based on the weight of the light filtering material.

In one embodiment, the semi-conductive nanoparticles are capped with an organic layer, an inorganic layer or a mixture thereof, and/or encapsulated in an inorganic matrix. In one embodiment, the matrix material is an organic material or an inorganic material. In one embodiment, the organic material is selected from allyl polymers, (meth)acrylic polymers; epoxy compounds; polyurethane, polythiourethane materials, or mixture thereof. In one embodiment, the inorganic material is selected from sol gel materials, mineral oxides, or mixture thereof.

The present invention also relates to a display comprising an image producing system and a light filtering material according to the invention.

The present invention also relates to a light filtering glass container comprising glass container partially or totally coated with the light filtering material according to the invention.

The present invention also relates to an ophthalmic lens comprising the light filtering material according to the invention.

The present invention also relates to a use of a light filtering material according to the invention as a light filtering material on a glass container, on an optical substrate of an ophthalmic lens, in a display.

### Definitions

In the present invention, the following terms have the following meanings:
“Absorbance” is the decimal logarithm of ratio I₀/I, where I₀ is the intensity of light incident on a sample and I is the intensity of light transmitted through said sample. Absorbance is measured for wavelengths in UV and visible range from 350 nm to 780 nm.
“Chroma” refers to the radial coordinate of a colour in CIE L*a*b* model. As chroma increases, saturation of colour increases. To the opposite, a low chroma correspond to a pale colour. In particular, chroma of white colour is zero.
“Color space”: refers to a model for representation of color perceived by observers. In this disclosure, color space is any of the system defined by the International Commission on Illumination (CIE). It may be CIE L*a*b* color space—also known as L*a*b*—defined by the International Commission on Illumination (CIE) in 1976. In CIE L*a*b*, a colour is represented by lightness (L*), position between red and green (a*) and position between yellow and blue (b*). Within this model, all colours for a given lightness can be represented within a circle, in which a* and b* are coordinates of colours. It may be CIE 1931 xyY colour space with associated CIE 1931 xy chromaticity diagram coordinates. It may also be CIE Luv colour space with associated u′, v′ chromaticity diagram coordinates. It may be CIE L*a*b* colour space with associated a, b chromaticity diagram coordinates.
“Colorimetric coefficients”: refer to chroma and hue of a colour, in the international colorimetric system CIE L*a*b* (1976), and are calculated between 380 and 780 nm, taking the standard illuminant D65 and the observer into account (angle of 2°). The observer is a “standard observer” as defined in the international colorimetric system CIE L*a*b*.
“Core/crown” refers to a heterostructure in which a central nanoparticle: the core, is surrounded by a band of material disposed on the periphery of the core: the crown.
“Core/shell” refers to a heterostructure in which a central nanoparticle: the core, is embedded by a layer of material disposed on the core: the shell. Two successive shells may be laid, yielding core/shell/shell heterostructure. Core and shell may have the same shape, for instance core is a nanosphere and shell is a layer of essentially constant thickness yielding a spherical core/shell nanoparticle. Core and shell may have different shapes, for instance a dot—a nanosphere or a nanocube or any other nanocluster—is provided as a core and shell is grown laterally around the core, yielding an heterostructure with shape of a nanoplate but comprising a dot inside the nanoplate: the latter is named dot in plate thereafter. In some embodiments, core and shell have different compositions. In other embodiments composition varies continuously from core to shell: there is no precise boundary between core and shell but properties in centre of the core are different from properties on the outer boundary of shell.
“Gamut” of a display: refers to the area of a color space, for example CIE 1931 xy chromaticity diagram, whose colours can be reproduced by said display. A display suing three light sources red, green and blue with colour properties represented by points R, G and B in CIE 1931 xy chromaticity diagram has a gamut defined the triangle limited by vertices R, G and B. Same approach applies with other color spaces, as CIE Luv for instance.
“Hue”: refers to the angular coordinate of a colour in CIE L*a*b* model. Hue is an indication of colour perceived as red, orange, yellow, green, blue or purple.
“Illuminant”: refers to a theoretical source of visible light. Standard illuminants are defined by International Commission on Illumination (CIE). For natural light, standard illuminant D65 is preferred as D65 is intended to represent average daylight. In specific conditions for artificial lightning, other illuminants are used.
“Lightness”; refers to the absolute brightness value of light. In CIE LAB colorimetric space, Lightness ranges from L*=0 (black) to L*=100 (diffuse white).
“Luminous transmission”: refers to an average in the 380-780 nm wavelength range that is weighted according to the sensitivity of the eye at each wavelength of the range and measured under D65 illumination conditions (daylight), as defined in the standard ISO 13666:1998.
“Nanometric size” refers to a size of matter in which quantum effects appear due to confinement. For semi-conductive nanoparticles, nanometric size has to be defined with the average Bohr radius of an electron/hole pair. Confinement is effective for size in at least one dimension of the object below 20 nm, preferably below 15 nm, more preferably below 10 nm. The stronger confinements are obtained with a size in at least one dimension below 5 nm.
“Nanoparticle” refers to a particle having a size in at least one of its dimensions below 100 nm. For a nanosphere, diameter should be below 100 nm. For a nanoplate, thickness should be below 100 nm. For a nanorod, diameter should be below 100 nm.
“Nanoplate” refers to a 2D shaped nanoparticle, wherein the smallest dimension of said nanoplate is smaller than the largest dimension of said nanoplate by a factor (aspect ratio) of at least 1.5, at least 2, at least 2.5, at least 3, at least 3.5, at least 4, at least 4.5, at least 5, at least 5.5, at least 6, at least 6.5, at least 7, at least 7.5, at least 8, at least 8.5, at least 9, at least 9.5 or at least 10.
“Semi-conductive nanoparticles” refers to particles made of a material having an electronic structure corresponding to semi-conductive materials known in electronic industry but having a nanometric size. Due to their specific electronic structure, semi-conductive materials behave as high-pass absorbing materials. Indeed, light having a wavelength more energetic than band gap may be absorbed by the semi-conductive material, yielding an electron/hole pair, an exciton, which later recombine in the material and dissipate heat, or emit light, or both. On the contrary, light having a wavelength less energetic than band gap cannot be absorbed: semi-conductive material is transparent for these wavelengths. In macroscopic semi-conductive materials, visible light is generally absorbed while near/mid infra-red light is not absorbed. When semi-conductive particles have a nanometric size, confinement—i.e. shape and nanometric size-governs electronic structure following the rules of quantum mechanics and light absorption may be limited to UV range or UV and high energy visible light. Within this disclosure, semi-conductive nanoparticles absorb light having a wavelength below a threshold, this threshold being in the range of 350 nm-800 nm.

### DETAILED DESCRIPTION

This invention relates to a light filtering material which comprises at least one matrix material and semi-conductive nanoparticles which are dispersed in said matrix material.

Said light filtering material absorbs light, and absorbance of said light filtering material has:
a local maximum absorbance of highest wavelength in the range from 350 to 500 nm, said local maximum having an absorbance value Aₘₐₓ for a wavelength λₘₐₓ,
a value of 0.9Aₘₐₓ for a wavelength λ_{0.9}, λ_{0.9} being greater than λₘₐₓ;
a value of 0.5Aₘₐₓ for a wavelength λ_{0.5}, λ_{0.5} being greater than λ_{0.9}; and
wherein |λ_{0.5}−λ_{0.9}| is less than 15 nm.

In a preferred configuration, |λ_{0.5}−λ_{0.9}| is less than 10 nm, or less than 5 nm.

In an embodiment, absorbance of said light filtering material has a value of 0.1Aₘₐₓ for a wavelength λ_{0.1}, λ_{0.1} being greater than λ_{0.9}; and wherein |λ_{0.1}−λ_{0.9}| is less than 30 nm, preferably less than 20 nm, more preferably less than 10 nm.

By proper selection of semi-conductive nanoparticles and matrix material, the wavelength λₘₐₓ of the light filtering material may be selected in the UV-visible range, i.e. between 400 nm and 500 nm, between 400 nm and 450 nm, between 450 nm and 500 nm, between 400 nm and 430 nm, between 430 nm and 460 nm, between 420 nm to 480 nm, between 400 nm and 410 nm, between 410 nm and 420 nm, between 420 nm and 430 nm, between 430 nm and 440 nm, between 440 nm and 450 nm, between 450 nm and 460 nm, between 460 nm and 470 nm, between 470 nm and 480 nm, between 480 nm and 490 nm, between 490 nm and 500 nm.

In this disclosure, semi-conductive nanoparticles bring especially interesting light absorbing properties to filters comprising them. In particular, with proper selection of composition and structure of semi-conductive nanoparticles, light absorbers having a sharp transition between range of absorbed light (of high energy) and range of transmitted light (low energy) may be designed. Semi-conductive nanoparticles absorb light having a wavelength below a threshold, this threshold being in the range of 350 nm-800 nm.

In this disclosure, semi-conductive nanoparticles are light absorbing agents. In this disclosure, absorbance of light of wavelength λ₀ by semi-conductive nanoparticles is defined as follows. Light of wavelength λ₀ is directed on a sample comprising semi-conductive nanoparticles. Thickness of the sample may by in the micrometric range for coatings or in the millimetric range for moulded materials. Intensity of directed light is I₀. The intensity I of light of wavelength λ₀ transmitted through the sample is measured. Absorbance light of wavelength λ₀ for is defined as the decimal logarithm of ratio I₀/I. Absorbance of 1 means that 9 out of 10 photons are absorbed by the sample. Absorbance of 0.3 means that 1 out of 2 photons is absorbed by the sample. Due to their electronic structure, semi-conductive nanoparticles behave as high pass filters: absorbance is high for wavelength of high energy, i.e. short wavelengths. On the contrary, absorbance for wavelength of low energy, i.e. long wavelengths, is low. The transition between both domains of high and low absorbance may be defined by the wavelength λₘₐₓ defined above.

In other words, light of wavelength inferior to the wavelength λₘₐₓ will not be transmitted whereas light of wavelength inferior to the wavelength λₘₐₓ will be transmitted. This way, light of wavelength inferior to the wavelength λₘₐₓ is “blocked” by the light filtering material. Advantageously, in the present disclosure, λₘₐₓ is in the blue part of visible range, allowing for attenuation of blue light. The wavelength λₘₐₓ of the light filtering material can be adjusted depending on the composition, shape, dimensions and direct environment of the semi-conductive nanoparticles.

In an embodiment, absorbance is higher than 0.5, preferably 1, more preferably 1.5 for each light wavelength ranging from 350 nm to λₘₐₓ.

In one embodiment, the light filtering material is a coating deposited on a substrate, a film to be deposited on a substrate, or a self-standing material.

In one embodiment, the coating is obtained by curing a Sol-Gel polymerizable composition and has a thickness in a range from 1 μm to 15 μm, preferably from 1 μm to 10 μm, more preferably from 2 μm to 6 μm.

In one embodiment, the coating is obtained by curing a composition comprising (meth)acrylics monomers or oligomers, epoxy monomers or oligomers, or mixture thereof. In particular, the thickness of coating obtained by curing said polymerizable composition is in a range from 2 μm to 100 μm, preferably from 3 μm to 50 μm, more preferably from 4 μm to 30 μm.

In one embodiment, the amount of semi-conductive nanoparticles in the light filtering material is from 10 ppm to 10 wt % by weight, in particular from 10 ppm to 1 wt %, based on the weight of the light filtering material, in particular from 20 ppm to 0.5 wt %, more particularly from 25 ppm to 0.25 wt %. In this disclosure, the organic or inorganic capping compound that is used to cap semi-conductive nanoparticles or the material that is used to encapsulate semi-conductive nanoparticles is not included in the amount of semi-conductive nanoparticles. For the sake of clarity, a light filtering material comprising 1 wt % of aggregates comprising 30 wt % of semi-conductive nanoparticles embedded in 70 wt % of a mineral capsule, comprises 0.3 wt % of semi-conductive nanoparticles. The wt % are calculated based on the theoretical dry extract of the light filtering material.

In one embodiment, the amount of matrix material is 70 to 99.9 wt % based on the weight of the light filtering material, preferably the amount of matrix material is 90 to 99 wt % based on the weight of the light filtering material.

In one embodiment, semi-conductive nanoparticles are uniformly dispersed in the matrix material, i.e. each nanoparticle is separated from its nearest neighbour nanoparticle by at least 5 nm, preferably 10 nm, more preferably 20 nm, even more preferably 50 nm, most preferably 100 nm. In other words, semi-conductive nanoparticles are not aggregated in the matrix material. Advantageously, the farther away the particles, the lower the diffusion.

In an embodiment, the semi-conductive nanoparticles comprised in the light filtering material have the same formula (I), shape and structure.

In another embodiment, the semi-conductive nanoparticles comprised in the light filtering material have different formula (I) and/or different shape and/or different structure. In this embodiment, absorbance of the light filtering material may be adjusted by superposition of absorbance of each type of semi-conductive nanoparticles, as taught by Beer-Lambert law.

The light filtering material may further comprise additives in conventional proportions. These additives include stabilizers such as antioxidants, colour balancing agents, UV light absorbers, light stabilizers, anti-yellowing agents, adhesion promoters, dyes, photochromic agents, pigments, rheology modifiers, lubricants, cross-linking agents, photo-initiators fragrances and pH regulators. They should not deteriorate optical properties of the light filtering material.

In an advantageous embodiment, the light filtering material does not comprise additional UV light absorbers. Indeed, semi-conductive nanoparticles present a significant absorbance for light wavelength ranging from 280 nm to λₘₐₓ. When λₘₐₓ is selected in the visible range, the whole UV-light ranging from 280 nm to 380 nm is absorbed by semi-conductive nanoparticles and no more UV light absorbers are required in the light filtering material.

In this disclosure, absorbance of a light filtering material is measured on a 5-micrometer-thick coating comprising semi-conductive nanoparticles or on a 2-millimeter-thick sample. In an embodiment, absorbance is higher than 0.5, preferably 1, more preferably 1.5 for each light wavelength ranging from 350 nm to λₘₐₓ. λₘₐₓ may be in the visible range, preferably in the range from 420 nm to 480 nm, preferably from 420 nm to 450 nm.

### Matrix Material

Suitable matrix material may be of any type, as soon as it is sufficiently transparent to visible light and allows for dispersion of the semi-conductive nanoparticles.

In one embodiment, the matrix material is an organic material or an inorganic material.

The organic material may be selected from allyl polymers, (meth)acrylic polymers; epoxy compounds; polyurethane, polythiourethane materials, or mixture thereof.

Suitable organic materials are obtained from a polymerizable composition comprising at least one monomer or oligomer and at least one catalyst for initiating the polymerization of said monomer or oligomer.

Suitable monomers or oligomers are selected from allylic compounds, (meth)acrylic compounds, epoxy compounds, compounds used to prepare polyurethane or polythiourethane materials. Mixtures of these monomers, or multifunctional monomers—in particular epoxy-acrylic compounds—are also suitable.

In this disclosure, an allyl monomer or allyl oligomer is a compound comprising an allyl group. Examples of suitable allyl compounds include diethylene glycol bis(allyl carbonate), ethylene glycol bis(allyl carbonate), oligomers of diethylene glycol bis(allyl carbonate), oligomers of ethylene glycol bis(allyl carbonate), bisphenol A bis(allyl carbonate), diallylphthalates such as diallyl phthalate, diallyl isophthalate and diallyl terephthalate, and mixtures thereof.

In this disclosure, a (meth)acrylic monomer or (meth)acrylic oligomer is a compound comprising having acrylic or methacrylic groups. (Meth)acrylates may be monofunctional (meth)acrylates or multifunctional (meth)acrylates.

Suitable (meth)acrylic monomers or oligomers are multifunctional (meth)acrylates and may be selected from the group consisting of diacrylate, triacrylate, tetraacrylate and hexaacrylate monomers, such as pentaerythritol triacrylate or pentaerythritol tetraacrylate. In particular, the polyfunctional monomer is preferably selected from the group consisting of 1,4-butanedioldiacrylate, 1,6-hexanedioldiacrylate, dipropyleneglycol diacrylate pentaerythritol triacrylate, pentaerythritol tetraacrylate, dipentaerythritol tetraacrylate, dipentaerythritol hexaacrylate, silicone hexaacrylate, and mixtures thereof. The use of multifunctional acrylate monomers results in improved scratch resistance and better adhesion to thermoplastic substrates like PET or polycarbonate.

In an embodiment especially adapted for polymerization of (meth)acrylic monomers or oligomers, the catalyst meant for initiating polymerization is a free radical initiator.

Suitable epoxy monomers or oligomers are multifunctional epoxy and may be selected from the group consisting of diglycerol tetraglycidyl ether, dipentaerythritol tetraglycidyl ether, sorbitol polyglycidyl ether, polyglycerol polyglycidyl ether, pentaerythritol polyglycidyl ether such as pentaerythritol tetraglycidyl ether, trimethylolethane triglycidyl ether, trimethylolmethane triglycidyl ether, trimethylolpropane triglycidyl ether, triphenylolmethane triglycidyl ether, trisphenol triglycidyl ether, tetraphenylol ethane triglycidyl ether, tetraglycidyl ether of tetraphenylol ethane, p-aminophenol triglycidyl ether, 1,2,6-hexanetriol triglycidyl ether, glycerol triglycidyl ether, diglycerol triglycidyl ether, glycerol ethoxylate triglycidyl ether, Castor oil triglycidyl ether, propoxylated glycerine triglycidyl ether, ethylene glycol diglycidyl ether, 1,4-butanediol diglycidyl ether, neopentyl glycol diglycidyl ether, cyclohexanedimethanol diglycidyl ether, dipropylene glycol diglycidyl ether, polypropylene glycol diglycidyl ether, dibromoneopentyl glycol diglycidyl ether, hydrogenated bisphenol A diglycidyl ether, (3,4-epoxycyclohexane) methyl 3,4-epoxycylohexylcarboxylate and mixtures thereof. The use of such polyepoxides improves toughness of the resulting cured coating and adhesion to thermoset resin substrates.

In an embodiment especially adapted for polymerization of epoxy monomers or oligomers, the catalyst—often referred to as hardening agents—meant for initiating polymerization is selected from amines, anhydrides, phenols or thiols.

In this disclosure, mixture of monomers or oligomers having at least two isocyanate functions with monomers or oligomers having at least two alcohol, thiol or epithio functions are suitable polymerizable compositions. Monomer or oligomer having at least two isocyanate functions may be selected from symmetric aromatic diisocyanate such as 2,2′ Methylene diphenyl diisocyanate (2,2′ MD I), 4,4′ dibenzyl diisocyanate (4,4′ DBDI), 2,6 toluene diisocyanate (2,6 TDI), xylylene diisocyanate (XDI), 4,4′ Methylene diphenyl diisocyanate (4,4′ MDI) or asymmetric aromatic diisocyanate such as 2,4′ Methylene diphenyl diisocyanate (2,4′ MDI), 2,4′ dibenzyl diisocyanate (2,4′ DBDI), 2,4 toluene diisocyanate (2,4 TDI) or alicyclic diisocyanates such as Isophorone diisocyanate (IPDI), 2,5(or 2,6)-bis(iso-cyanatomethyl)-Bicyclo[2.2.1]heptane (NDI) or 4,4′ Diisocyanato-methylenedicyclohexane (H12MD I) or aliphatic diisocyanates such as hexamethylene diisocyanate (HDI) or mixtures thereof. Monomer or oligomer having thiol function may be selected from Pentaerythritol tetrakis mercaptopropionate, Pentaerythritol tetrakis mercaptoacetate, 4-Mercaptomethyl-3,6-dithia-1,8-octanedithiol, 4-mercaptomethyl-1,8-dimercapto-3,6-dithiaoctane, 2,5-dimercaptomethyl-1,4-dithiane, 2,5-bis[(2-mercaptoethyl)thiomethyl]-1,4-dithiane, 4,8-dimercaptomethyl-1, 1 1-dimercapto-3,6,9-trithiaundecane, 4,7-dimercaptomethyl-1, 1 1-dimercapto-3,6,9-trithiaundecane, 5,7-dimercaptomethyl-1, 1 1-dimercapto-3,6,9-trithiaundecane and mixture thereof. Monomer or oligomer having epithio function may be selected from bis(2,3-epithiopropyl) sulfide, bis(2,3-epithiopropyl) disulfide and bis[4-(beta epithiopropylthio)phenyl]sulfide, bis[4-(beta-epithiopropyloxy)cyclohexyl]sulfide.

In an embodiment, the composition of the polymerizable composition yielding polyurethane or polythiourethane materials is stoichiometric. In an embodiment especially adapted to compositions yielding polyurethane or polythiourethane materials, the catalyst meant for initiating polymerization is an organotin compound.

The inorganic material may be selected from sol gel materials, mineral oxides, or mixture thereof.

Suitable mineral oxides are SiO₂, Al₂O₃, TiO₂, ZrO₂, FeO, ZnO, MgO, SnO₂, Nb₂O₅, CeO₂, BeO, IrO₂, CaO, Sc₂O₃, Na₂O, BaO, K₂O, TeO₂, MnO, B₂O₃, GeO₂, As₂O₃, Ta₂O₅, Li₂O, SrO, Y₂O₃, HfO₂, MoO₂, Tc₂O₇, ReO₂, Co₃O₄, OsO, RhO₂, Rh₂O₃, CdO, HgO, Tl₂O, Ga₂O₃, In₂O₃, Bi₂O₃, Sb₂O₃, PoO₂, SeO₂, Cs₂O, La₂O₃, Pr₆O₁₁, Nd₂O₃, La₂O₃, Sm₂O₃, Eu₂O₃, Tb₄O₇, Dy₂O₃, Ho₂O₃, Er₂O₃, Tm₂O₃, Yb₂O₃, Lu₂O₃, Gd₂O₃, or a mixture thereof.

Suitable inorganic materials are obtained from a polymerizable Sol Gel composition comprising at least one monomer or oligomer and at least one catalyst for initiating the polymerization of said monomer or oligomer. Monomers or oligomers may be selected from alkoxysilanes, alkylalkoxysilanes, epoxysilanes, epoxyalkoxysilanes, and mixtures thereof. These monomers or oligomers may be prepared in a solvent to form the polymerizable composition. Suitable solvents are polar solvents, such as water/alcohol mixtures.

Alkoxysilanes may be selected among compounds having the formula: RₚSi(Z)₄₋ₚ in which the R groups, identical or different, represent monovalent organic groups linked to the silicon atom through a carbon atom, the Z groups are identical or different and represent hydrolyzable groups or hydrogen atoms, p is an integer ranging from 0 to 2. Suitable alkoxysilanes may be selected in the group consisting of tetraethoxysilane Si(OC₂H₅)₄ (TEOS), tetramethoxysilane Si(OCH₃)₄ (TMOS), tetra(n-propoxy)silane, tetra(i-propoxy)silane, tetra(n-butoxy)silane, tetra(sec-butoxy)silane or tetra(t-butoxy)silane.

Alkylalkoxysilanes may be selected among compounds having the formula: RₙYₘSi(Z₁)₄₋ₙ₋ₘ in which the R groups, identical or different, represent monovalent organic groups linked to the silicon atom through a carbon atom, the Y groups, identical or different, represent monovalent organic groups linked to the silicon atom through a carbon atom, the Z groups are identical or different and represent hydrolyzable groups or hydrogen atoms, m and n are integers such that m is equal to 1 or 2 and n+m=1 or 2.

Epoxyalkoxysilanes may be selected among compounds having the formula: RₙYₘSi(Z₁)₄₋ₙ₋ₘ in which the R groups, identical or different, represent monovalent organic groups linked to the silicon atom through a carbon atom, the Y groups, identical or different, represent monovalent organic groups linked to the silicon atom through a carbon atom and containing at least one epoxy function, the Z groups are identical or different and represent hydrolyzable groups or hydrogen atoms, m and n are integers such that m is equal to 1 or 2 and n+m=1 or 2.

Suitable epoxysilanes may be selected from the group consisting of glycidoxy methyl trimethoxysilane, glycidoxy methyl triethoxysilane, glycidoxy methyl tripropoxysilane, α-glycidoxy ethyl trimethoxysilane, α-glycidoxy ethyl triethoxysilane, β-glycidoxy ethyl trimethoxysilane, β-glycidoxy ethyl triethoxysilane, β-glycidoxy ethyl tripropoxysilane, α-glycidoxy propyl trimethoxysilane, α-glycidoxy propyl triethoxysilane, α-glycidoxy propyl tripropoxysilane, β-glycidoxy propyl trimethoxysilane, β-glycidoxy propyl triethoxysilane, β-glycidoxy propyl tripropoxysilane, γ-glycidoxy propyl trimethoxysilane, γ-glycidoxy propyl triethoxysilane, γ-glycidoxy propyl tripropoxysilane, 2-(3,4-epoxycyclohexyl) ethyltrimethoxysilane, 2-(3,4-epoxycyclohexyl) ethyltriethoxysilane.

In an embodiment especially adapted to compositions yielding Sol-Gel materials, the catalyst meant for initiating polymerization is a Lewis Acid.

### Semi-Conductive Nanoparticles

Materials may have various compositions and structures. Among mineral materials, some are electrically conductive, for instance metals. Some are electrically insulating, such as silicon oxide or tin oxide. Of particular interest in this disclosure are materials made of semi-conductive materials, well known in electronic industry. Semi-conductive materials may have a macroscopic size. If semi-conductive materials have a nanometric size, their electronic and optical properties are modified.

In one embodiment, the semi-conductive nanoparticles comprise a material of formula

MₓQ_{y}E_{z}A_{w} (I),

wherein:
M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
E is selected from the group consisting of O, S, Se, Te, C, N, P, As, Sb, F, Cl, Br, I, or a mixture thereof;
A is selected from the group consisting of O, S, Se, Te, C, N, P, As, Sb, F, Cl, Br, I, or a mixture thereof; and
x, y, z and w are independently a decimal number from 0 to 5; x, y, z and w are not simultaneously equal to 0; x and y are not simultaneously equal to 0; z and w may not be simultaneously equal to 0.

In particular, semi-conductive nanoparticles may comprise a material of formula MₓE_{y}, in which M is Zn, Cd, Hg, Cu, Ag, Al, Ga, In, Si, Ge, Pb, Sb or a mixture thereof; and E is O, S, Se, Te, N, P, As or a mixture thereof. x and y are independently a decimal number from 0 to 5, with the proviso that x and y are not 0 at the same time.

In a specific embodiment, the semi-conductive nanoparticles comprise a material selected from the group consisting of CdS, CdSe, CdTe, ZnS, ZnSe, ZnTe, HgS, HgSe, HgTe, HgO, GeS, GeSe, GeTe, SnS, SnSe, SnTe, PbS, PbSe, PbTe, GeS₂, GeSe₂, SnS₂, SnSe₂, CuInS₂, CuInSe₂, AgInS₂, AgInSe₂, CuS, Cu₂S, Ag₂S, Ag₂Se, Ag₂Te, FeS, FeS₂, InP, Cd₃P₂, Zn₃P₂, CdO, ZnO, FeO, Fe₂O₃, Fe₃O₄, Al₂O₃, TiO₂, MgO, MgS, MgSe, MgTe, AlN, AIP, AlAs, AlSb, GaN, GaP, GaAs, GaSb, InN, InP, InAs, InSb, TlN, TlP, TlAs, TlSb, MoS₂, PdS, Pd₄S, WS₂, CsPbCl₃, PbBr₃, CsPbBr₃, CH₃NH₃PbI₃, CH₃NH₃PbCl₃, CH₃NH₃PbBr₃, CsPbI₃, FAPbBr₃ (where FA stands for formamidinium), or a mixture thereof.

In a preferred configuration of this embodiment, the semi-conductive nanoparticles comprise CdS or ZnSe.

In this disclosure, semi-conductive nanoparticles may have different shapes, provided that they present a nanometric size leading to confinement of exciton created in the nanoparticle.

In a specific configuration, semi-conductive nanoparticles may have nanometric sizes in three dimensions, allowing confinement of excitons in all three spatial dimensions. Such nanoparticles are for instance nanocubes or nanospheres also known as nanodots 1 as shown on FIG. 1.

In another specific configuration, semi-conductive nanoparticles may have a nanometric sizes in two dimensions, the third dimension being larger: excitons are confined in two spatial dimensions. Such nanoparticles are for instance nanorods, nanowires or nanorings.

In another specific configuration, semi-conductive nanoparticles may have a nanometric size in one dimension, the other dimensions being larger: excitons are confined in one spatial dimension only. Such nanoparticles are for instance nanoplates 2 (also called nanoplatelets) as shown on FIG. 1, nanosheets, nanoribbons or nanodisks.

Semi-conductive nanoparticles may be nanospheres, nanoplates (also called nanoplatelets) or nanorods.

According to one embodiment, the semi-conductive nanoparticles comprise at least 1%, 5%, 10%, 15%, 20%, 25%, 30%, 35%, 40%, 45%, 50%, 55%, 60%, 65%, 70%, 75%, 80%, 85%, 90%, 95%, or 100% of semiconductor nanoplates.

The exact shape of semi-conductive nanoparticles defines confinement properties; then electronic and optical properties depending on composition of semi-conductive nanoparticle, in particular the band gap, then λₘₐₓ of the final light filtering material. It has been also observed that nanoparticles with a nanometric size in one dimension, especially nanoplates, present a sharper decreasing zone as compared to nanoparticles with other shapes. Indeed, width of decreasing zone is enlarged if nanometric size of nanoparticles fluctuates around a mean value. When nanometric size is controlled in only one dimension, i.e. for nanoplates, by a strict number of atomic layers, thickness fluctuations are almost null and transition between absorbing and non-absorbing state is very sharp. This leads to particularly effective light filters. In addition, semi-conductive particle are mineral materials able to withstand conditions in which organic light absorbers are degraded.

In a preferred embodiment, semi-conductive nanoparticles are homostructures. By homostructure, it is meant that the nanoparticle is homogenous and has the same local composition in all its volume. In other words, such semi-conductive nanoparticles are core nanoparticles, as opposed to “core/shell” or “core/crown” nanoparticles, i.e. do not comprise a shell or a crown made of a different material than the core. This is advantageous as, adding a shell or crown on a nanoparticle may lead to a less abrupt transition between light absorption/transmission regimes.

In an alternative embodiment, semi-conductive nanoparticles are heterostructures. By heterostructure, it is meant that the nanoparticle is comprised of several sub-volumes, each sub-volume having a different composition from neighbouring sub-volumes. In a particular embodiment, all sub-volumes have a composition defined by formula (I) disclosed above, with different parameters, i.e. elemental composition and stoichiometry.

In this embodiment, the semi-conductive nanoparticles may be core/shell nanoparticles or core/crown nanoparticles as detailed hereafter, the core being a different material from the shell or crown.

Example of heterostructure are core/shell nanoparticles as shown on FIG. 1, the core having any shape disclosed above: nanosphere 11 or 44, nanoplate 33. A shell is a layer covering totally or partially the core: nanosphere 12, nanoplate 34 or 45. A particular example of core/shell heterostructure is a multi-layered structure comprising a core and several successive shells: nanospheres 12 and 13, nanoplates 34 and 35. For convenience, these multi-layered heterostructures are named core/shell hereafter. Core and shell may have the same shape-sphere 11 in sphere 12 for example—or not—dot 44 in plate 45 for instance.

Another example of heterostructure are core/crown nanoparticles as shown on FIG. 1, the core having any shape disclosed above. A crown 23 is a band of material disposed on the periphery of the core 22—here a nanoplate. This heterostructure is particularly useful with cores being nanoplates and crown disposed on the edges of the nanoplate.

FIG. 1 shows clear boundaries between core on one hand and shell or crown on the other hand. Heterostructures also enclose structures in which composition varies continuously from core to shell/crown: there is no precise boundary between core and shell/crown but properties in centre of the core are different from properties on the outer boundary of shell/crown.

In an advantageous embodiment, semi-conductive nanoparticles have a largest dimension below 500 nm, in particular below 300 nm, ideally below 200 nm. Semi-conductive nanoparticles of small size do not induce light scattering when dispersed in a material having a different refractive index.

In a specific configuration of the previous embodiment, the spherical semi-conductive nanoparticles have a mean diameter ranging from 1 nm to 50 nm, preferably from 2 nm to 25 nm, more preferably from 2 nm to 10 nm, even more preferably from 4 nm to 8 nm.

In a specific configuration of the previous embodiment, semi-conductive nanoparticles have a mean thickness ranging from 0.1 nm to 20 nm, preferably from 0.5 nm to 10 nm, more preferably from 0.5 nm to 2.5 nm, a mean width ranging from 5 nm to 100 nm, preferably from 10 nm to 50 nm, more preferably from 10 nm to 30 nm, and/or a mean length ranging from 5 nm to 100 nm, preferably from 10 nm to 50 nm, more preferably from 10 nm to 30 nm.

Table 1 below discloses various semi-conducting nanoparticles suitable for use in this disclosure.

TABLE 1
Table 1: Semi-conducting nanoparticles suitable for light filtering materials
(1 wt % of semi-conducting nanoparticles in matrix material).

| | | | Dimensions | Composition - formula (I) | | | | λₘₐₓ |
|---|---|---|---|---|---|---|---|---|
| | Shape | Homo/Hetero structure | (nm) | Mx | Qy | Ez | Aw | (nm) |
| 1 | Sphere | Homo | 2.8 | Cd 1 | — | Se 1 | — | 500 |
| 2 | Plate | Homo | 1.2*15*25 | Cd 1 | — | S 1 | — | 418 |
| 3 | Plate | Core/Crown | Core: 1.2*15*15 | Cd 1 | — | Se 1 | — | 407 |
| | | | Crown: 1.2*20*20 | Cd 1 | — | S 1 | — | |
| 4 | Plate | Core(Plate)/Shell | Core: 1.2*10*15 | Cd 1 | — | Se 1 | — | 602 |
| | | | Shell: 3*15*20 | Zn 1 | — | S 1 | — | |
| 5 | Plate | Core(gradient)/Shell | Core: gradient | Cd 1 | — | Se 0.5 | S 0.5 | 430 |
| | | (Dot in Plate) | Shell: 1.2*15*15 | Cd 1 | — | — | S 1 | |
| 6 | Plate | Core(Plate)/Shell | Core: 1.2*10*15 | Cd 1 | — | Se 0.3 | S 0.7 | 478 |
| | | | Shell: 3*15*20 | Cd 0.1 | Zn 0.9 | S 1 | — | |
| 7 | Sphere | Homo | 5.8 | Zn 1 | — | Se 1 | — | 387 |
| 8 | Plate | Homo | 1.9*15*30 | Zn 1 | — | Se 1 | — | 382 |

Wavelength λₘₐₓ of ZnSe nanospheres and ZnSe nanoplates described in Table 1 (lines 7 and 8) ranges from 400 nm to 480 nm after ligand exchange, as disclosed in the examples of the present disclosure.

In one embodiment, the semi-conductive nanoparticles are capped with an organic layer, an inorganic layer or a mixture thereof, and/or encapsulated in an inorganic matrix.

In a specific configuration of this embodiment, semi-conductive nanoparticles are capped with organic compounds or inorganic compounds (referred as capping compounds), said organic or inorganic compounds forming an organic or inorganic layer at the surface of each nanoparticle. By capped, it is meant that capping compounds are adsorbed or absorbed on the surface of the semi-conductive nanoparticle. Capping compounds provide several advantages. In particular, capping compounds may behave as dispersing agents, avoiding semi-conductive nanoparticles agglomeration in light filtering material. Besides, capping compounds may influence optical properties of semi-conductive nanoparticles as they modify boundary conditions of nanoparticles: λₘₐₓ of the final light filtering material may be adjusted by selection of capping compounds.

Example of suitable organic caping compounds are ligands comprising at least one chemical moiety M_{A} having an affinity to the surface of the semi-conductive nanoparticle, by any kind of intermolecular interactions.

In particular, M_{A} may have an affinity for a metal element present at the surface of the semi-conductive nanoparticle. M_{A} may be a thiol, a dithiol, an imidazole, a catechol, a pyridine, a pyrrole, a thiophene, a thiazole, a pyrazine, a carboxylic acid or carboxylate, a naphthyridine, a phosphine, a phosphine oxide, a phenol, a primary amine, a secondary amine, a tertiary amine, a quaternary amine or an aromatic amine.

Alternatively, M_{A} may have an affinity for a non-metal element selected from the group of O, S, Se, Te, C, N, P, As, Sb, F, Cl, Br, I present at the surface of the semi-conductive nanoparticle. M_{A} may be an imidazole, a pyridine, a pyrrole, a thiazole, a pyrazine, a naphthyridine, a phosphine, a phosphine oxide, a primary amine, a secondary amine, a tertiary amine, a quaternary amine or an aromatic amine.

Ligands may comprise several chemical moieties M_{A}, identical or different. Ligands may be a polymer having chemical moieties M_{A}, identical or different, as pending groups along the polymer backbone or repeated groups in the polymer backbone.

Example of suitable inorganic caping compounds are inorganic ligands such as S²⁻, HS⁻, Se²⁻, Te²⁻, OH⁻, BF₄⁻, PF₆⁻, Cl⁻, Br⁻, I⁻, As₂Se₃, Sb₂S₃, Sb₂Te₃, Sb₂Se₃, As₂S₃ or a mixture thereof.

In another specific configuration, semi-conductive nanoparticles are encapsulated within a matrix, forming capsules. By encapsulated, it is meant that semi-conductive nanoparticles are dispersed within an encapsulating material so that the encapsulating material covers all surface of semi-conductive nanoparticles. In other words, encapsulating material forms a barrier around semi-conductive nanoparticles. Such a barrier as several advantages. In particular, semi-conductive nanoparticles may be protected against chemicals, e.g. moisture, oxidants. Besides, semi-conductive nanoparticles that are not dispersible in a medium may be encapsulated in a material whose compatibility with said medium is good: the barrier behaves as a compatibilization agent. Last, encapsulated semi-conductive nanoparticles may be under the form of a powder dispersible in a medium instead of a dispersion in a solvent, thereby providing with easier handling in current processes.

Encapsulating material may be organic, in particular organic polymers. Suitable organic polymers are polyacrylates; polymethacrylates; polyacrylamides; polyamides; polyesters; polyethers; polyoelfins; polysaccharides; polyurethanes (or polycarbamates), polystyrenes; polyacrylonitrile-butadienestyrene (ABS); polycarbonate; poly(styrene acrylonitrile); vinyl polymers such as polyvinyl chloride; polyvinyl alcohol, polyvinyl acetate, polyvinylpyrrolidone, polyvinyl pyridine, polyvinylimidazole; poly(p-phenylene oxide); polysulfone; polyethersulfone; polyethylenimine; polyphenylsulfone; poly(acrylonitrile styrene acrylate); polyepoxides, polythiophenes, polypyrroles; polyanilines; polyaryletherketones; polyfurans; polyimides; polyimidazoles; polyetherimides; polyketones; polynucleotides; polystyrene sulfonates; polyetherimines; polyamic acid; or any combinations and/or derivatives and/or copolymers thereof.

Encapsulating material may be an inorganic material, such as mineral, in particular mineral oxides or mixture of mineral oxides. Suitable mineral oxides are SiO₂, Al₂O₃, TiO₂, ZrO₂, FeO, ZnO, MgO, SnO₂, Nb₂O₅, CeO₂, BeO, IrO₂, CaO, Sc₂O₃, Na₂O, BaO, K₂O, TeO₂, MnO, B₂O₃, GeO₂, As₂O₃, Ta₂O₅, Li₂O, SrO, Y₂O₃, HfO₂, MoO₂, Tc₂O₇, ReO₂, Co₃O₄, OsO, RhO₂, Rh₂O₃, CdO, HgO, Tl₂O, Ga₂O₃, In₂O₃, Bi₂O₃, Sb₂O₃, PoO₂, SeO₂, Cs₂O, La₂O₃, Pr₆O₁₁, Nd₂O₃, La₂O₃, Sm₂O₃, Eu₂O₃, Tb₄O₇, Dy₂O₃, Ho₂O₃, Er₂O₃, Tm₂O₃, Yb₂O₃, Lu₂O₃, Gd₂O₃, or a mixture thereof. Preferred mineral encapsulating materials are SiO₂, Al₂O₃ and ZnO. In particular, nanoparticules comprising Zn may be encapsulated by ZnO or SiO₂ and nanoparticles comprising Cd may be encapsulated by SiO₂, Al₂O₃ or mixture of SiO₂ and Al₂O₃.

The amount of semi-conductive nanoparticles in a capsule according to the present disclosure may be from 1.0 to 90% by weight, in particular from 2.5 to 50% by weight, more particularly from 3.0 to 25% by weight, based on the total weight of the capsule.

In an advantageous embodiment, capsules are nanoparticles, with a largest dimension below 500 nm, in particular below 300 nm, ideally below 200 nm. Capsules of small size do not induce light scattering when dispersed in a material having a different refractive index.

### ZnSe Nanoparticles

In a preferred embodiment, the semi-conductive nanoparticles are ZnSe nanoparticles, in particular ZnSe nanospheres or ZnSe nanoplates.

In this embodiment, ZnSe nanoparticles are monodisperse. “Monodisperse” refers to a deviation of the mean diameter or mean thickness inferior than 20%, 15%, 10%, preferably 5%.

In a specific configuration of this embodiment, ZnSe nanospheres have a mean diameter ranging from 1 nm to 30 nm, preferably from 1 nm to 20 nm, more preferably from 1 nm to 15 nm.

In another specific configuration of this embodiment, ZnSe nanoplates have a mean thickness ranging from 0.1 nm to 10 nm, preferably from 0.5 nm to 5 nm, more preferably from 0.5 nm to 2.5 nm. ZnSe nanoplates also have an aspect ratio superior to 1.5.

In this embodiment, ZnSe nanoparticles are homostructures.

In this embodiment, ZnSe nanoparticles may be doped with at least one element M and/or E, wherein M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof, and E is selected from the group consisting of O, S, Se, Te, C, N, P, As, Sb, F, Cl, Br, I, or a mixture thereof. In this disclosure, doping is induced by presence of impurity or impurities, such as elements M or E as described hereabove.

According to one embodiment, the doping level ranges from 1 to 10 molar %. Advantageously, doping ZnSe nanoparticles with at least one element M and/or E as described hereabove induces a shift of λₘₐₓ to higher wavelengths.

In another embodiment, one light filtering material comprises several populations of ZnSe nanoparticles, i.e. ZnSe nanoparticles having different doping levels and/or different shape and/or different structure and/or different size. ZnSe nanoparticles may also be encapsulated in different capsules.

### Process of Preparation of a Light Filtering Material

The present invention also relates to a process for the preparation of the light filtering material of the invention. Said process comprises the steps of:
a. providing a precursor of the matrix material;
b. providing semi-conductive nanoparticles in the form of a powder dispersible within said precursor or in the form of a dispersion of said semi-conductive nanoparticles in a liquid dispersible within said precursor;
c. optionally providing a catalyst for initiating the reaction to yield the matrix material from the precursor; and
d. mixing said precursor, said semi-conductive nanoparticles and optionally said catalyst to yield a homogeneous polymerizable composition.

Matrix materials are obtained from a polymerizable composition comprising at least one monomer or oligomer and at least one catalyst for initiating the polymerization of said monomer or oligomer. Thus, suitable precursors of matrix materials are monomers or oligomers as disclosed herein.

In the first step, when the light filtering material comprises several precursors, said precursors may be provided as a mixture or as separate compositions.

These precursors may be prepared in a solvent to form a polymerizable composition. Suitable solvents are polar solvents, such as water/alcohol mixtures.

In the second step, semi-conductive nanoparticles are provided. To ensure adequate dispersion in the light filtering material, i.e. in the matrix material, semi-conductive nanoparticles may be in the form of a powder dispersible in the precursor of matrix material. Alternatively, semi-conductive nanoparticles may be dispersed in a liquid, such as a solvent, said liquid being dispersible within said precursor of matrix material.

In the third step, a catalyst may be provided.

In an embodiment, the amount of catalyst is 0.1 to 5% by weight based on the weight of the polymerizable composition.

The polymerizable composition may further comprise a solvent, provided that polymerization is not hindered by the solvent. Solvent may be selected from polar solvents, like water, an alcohol, or water/alcohol mixtures, preferably an alcohol, e.g. methanol, ethanol, n-propanol, isopropanol, n-butanol, isobutanol, sec-butanol, tert-butanol, n-amylic alcohol, isoamylic alcohol, sec-amylic alcohol, tert-amylic alcohol, 1-ethyl-1-propanol, 2-methyl-1-butanol, 1-methoxy-2-propanol n-hexanol, cyclohexanol, ethyl cellosolve (monoethoxy ethylene glycol), and ethylene glycol.

The amount of precursor of matrix material according to the present disclosure may be from 20 to 99.9% by weight, in particular from 50 to 99.5% by weight, more particularly from 80 to 99% by weight, even more particularly from 90 to 99% by weight, based on the theoretical dry extract of the composition. By the theoretical dry extract of the composition, it is meant the weight of the composition from which all solvent and volatile moieties released during polymerization.

In a fourth step, precursor of matrix material, semi-conductive nanoparticles and optionally catalyst are mixed together to yield a homogeneous polymerizable composition. Mixing process may be realized in any order. In some embodiments, polymerization begins as soon as precursors are mixed with catalyst: in this case, catalyst is added last. In some embodiment, at least two precursors having different chemical functions are co-polymerized and polymerization begins as soon as precursors are mixed with catalyst: in this case a composition comprising one precursor and catalyst may be prepared, then mixed last with other precursors.

To be used and yield the final light filtering material, the polymerizable composition is deposited on a substrate, coated on a substrate, sprayed on a substrate or casted in a mould, before, during or after polymerization has taken place.

### Display

The present invention also relates to a display comprising an image producing system and a light filtering material. In said display, the light filtering material is intended to limit emission of high energy blue light, so as to protect eyes of users.

An image producing system is a light source configured to produce an image visible by human eye.

In an embodiment, said image is obtained by projection of light on a screen. In this embodiment, the image producing systems comprises a light source, lenses for image projection and a screen. The light filtering material may be located in any place on the light path: in the light source, as a layer between light source and lenses, or as a coating on lenses. This embodiment corresponds to projectors.

In another embodiment, said image is obtained by forming an array of pixels from a single light source, each pixel having a specific colour, thus forming a digital image. In this embodiment represented on FIG. 6, the image producing systems 5 may comprise a light source 51, usually known as backlight unit, a polarizing layer 52, an active matrix 53, a layer of liquid crystal 54 and a protective layer 55. The active matrix is configured to define the array of pixels as well as their colour: a unique light source is used (either blue or white) and light emitted by this source is converted into green and red colours by fluorescence phenomenon. The liquid crystal layer is configured to control intensity of each pixel. The light filtering material 6 may be located in any place on the light path: in the light source, as a layer between two successive components of the image producing system, or as a coating on any components of the image producing system. Preferably, the light filtering material is a coating applied on the internal side of the protective layer 55. In this position, the light filtering material is protected from environment and is the last (except protective layer) filter on the light path. In this last position, the amount of light incident on the light filtering material is reduced as compared to a position on the backlight unit, thus the light filtering material is less exposed to heat. This embodiment corresponds to LED displays.

In another embodiment, said image is obtained by forming an array of pixels, each pixel being a light source with a specific colour, thus forming a digital image. Usually, three colours are used as sources: red, green and blue, three pixels of different colours being mixed to form one pixel of desired colour obtained by addition. In this embodiment, intensity of each pixel may be adjusted separately. Light sources are protected by a protective layer. The light filtering material may be located in any place on the light path: on the blue light sources only or on the protective layer. Preferably, the light filtering material is a coating applied on the internal side of the protective layer. This embodiment corresponds to OLED or microLED displays.

In this disclosure, the image producing system has a gamut G₀ defined in a colour space. Any colour space is suitable to define gamut. Suitable colour spaces are CIE 1931 xyY and CIE Luv. The gamut G₀ is measured as an area in the colour space.

In this disclosure, the image producing system with the light filtering material has a gamut G₁ defined in the same colour space as for gamut G₀. In addition, the area of the gamut G₁ is greater than 90% of the area of the gamut G₀. Preferably, the area of the gamut G₁ is greater than 95% of the area of the gamut G₀.

In particular, when CIE xyY color space is used, the area of the gamut G₁ is greater than 90% of the area of the gamut G₀. Preferably, the area of the gamut G₁ is greater than 95% of the area of the gamut G₀. More preferably, the area of the gamut G₁ is greater than 98% of the area of the gamut G₀.

Alternatively, when CIE Luv color space is used, the area of the gamut G₁ is greater than 90% of the area of the gamut G₀. Preferably, the area of the gamut G₁ is greater than 95% of the area of the gamut G₀.

FIG. 7 shows the effect of light filtering material on gamut of a display comprising three light sources (red, green and blue, identified by point R, G and B in CIE xy chromaticity diagram) in the image producing system. Light filtering material has almost no effect on red and green sources as they emit at wavelength much larger than λₘₐₓ. However, the position of blue source in chromaticity diagram is slightly changed by light filtering material, as shown by the arrow, and located in B′. Indeed, light of highest energy (lowest wavelength) of the blue source is filtered out by the light filtering filter. Finally, area of gamut G₀ (without light filtering material-light grey) is reduced to the area of gamut G₁ (hatched in solid black).

### Glass Container

The present invention also relates to a light filtering glass container comprising a glass container partially or totally coated with the light filtering material according to the invention. The light filtering material is intended to protect to content of the glass container against high energy light radiation.

In this disclosure, glass is meant for two types of materials: a mineral material essentially made of fused silica (for containing beverages or liquid food products, e.g. bottles or flasks), or a polymeric material with very high optical performances, looking like mineral glass (for packaging luxury goods, e.g. based on polyethylene terephthalate (PET) or polycarbonate). White glass containers, i.e., glass containers having almost no colour are especially suitable.

The colour of glass container is determined by well know colorimetric measurements. A piece of glass is illuminated with a standard illuminant and light transmitted through the glass is analyzed according to CIE L*a*b* model (standard observer, 2°), yielding Lightness L*ug, Chroma C*ug and hue h*ug (ug stand for uncoated glass). Representation of colour with chroma and hue is especially appropriate for white glass, as colour of white glass approaches a zero chroma, and hue is not relevant in this case.

Alternatively, the colour of a glass container is determined from the measurement of transmission spectrum with any kind of light source. By combination of the transmission spectrum with the known spectrum of illuminant D65, one is able to simulate the spectrum of light transmitted through the glass container, then compute the colour of glass container.

In addition, measure of luminous transmittance—noted Tv hereafter—through the glass container gives an indication of Lightness. Indeed, a glass container with a low chroma will appear grey if Tv is low and bright if Tv is high.

Preferred glass containers have a chroma lower than 10 and a luminous transmittance Tv higher than 90%.

In the specific case of light filtering glass containers, filtering of light having wavelength longer than 480 nm is not particularly desirable as it would result in a decrease in lightness and strong colouring effect, which are undesirable.

To the contrary, light filtering material herein disclosed does not change significantly lightness of the glass container onto which it is coated. In other words, said coating is highly clear. So as to evaluate this performance, the colour of the glass container with the light filtering material is measured according to the method disclosed above for uncoated glass container, yielding Lightness L*cg, Chroma C*cg and hue h*cg (cg stand for coated glass). In this disclosure, the difference of lightness between the uncoated glass container and the glass container with the light filtering material is lower than 5, lower than 4, preferably lower than 3, more preferably lower than 2.

In an embodiment, the Chroma C*cg of the light filtering glass container is lower than 60, preferably lower than 50. Even if this chroma may appear large, colour balancing additives may be added to the light filtering material to lower chroma but with a lowering of lightness.

In a particular embodiment, the difference of lightness between the uncoated glass container and the glass container with the light filtering material is lower than 2 and the Chroma C*cg of the light filtering glass container is lower than 60.

In an embodiment, the luminous transmission of the glass container with the light filtering material is greater than 90%, preferably greater than 95%, of the luminous transmission of the uncoated glass container. In these conditions, the lightness of the glass container is not degraded by the light filtering material.

### Ophthalmic Lens

The present invention also relates to an ophthalmic lens comprising the light filtering material according to the invention. The light filtering material is intended to protect human eye against high energy radiations and optimize colour perception.

In a preferred embodiment, the wavelength λₘₐₓ of the light filtering material or ophthalmic lens may be selected between 400 nm and 500 nm.

Ophthalmic lenses behave as high pass filters: absorbance is high for wavelength of high energy, i.e. short wavelengths. On the contrary, absorbance for wavelength of low energy, i.e. long wavelengths, is low. The transition between both domains of high and low absorbance may be defined by the wavelength λₘₐₓ for which absorbance is higher than 0.5, preferably 1, more preferably 1.5 for each light wavelength ranging from 350 nm to λₘₐₓ.

In a particular embodiment, λₘₐₓ is in the blue part of visible range, i.e. between 400 nm and 480 nm, allowing for attenuation of blue light. Such ophthalmic lenses are particularly suitable for night drivers, as blue light emitted by car headlamps is becoming increasingly rich in blue light which is strongly scattered. Such ophthalmic lenses are also particularly suitable for intense users of digital devices, i.e. computers, smartphones and more generally devices with a digital display; as blue light emitted by displays is now suspected to be source of various troubles including circadian rhythm and age-related macular degeneration inter alia.

In another particular embodiment, λₘₐₓ is in the yellow-green part of visible range, i.e. between 480 nm and 500 nm, allowing for attenuation of blue and yellow light. Such ophthalmic lenses are particularly suitable for elderly people, who are usually very sensitive to central green spectrum of daylight.

In one embodiment, the ophthalmic lens comprises an ophthalmic substrate partially or totally coated with the light filtering material according to the invention. In a preferred configuration of this embodiment, the light filtering material is a coating with a thickness ranging from 0.5 μm to 20 μm, preferably from 1 μm to 15 μm, more preferably from 1 μm to 10 μm, most preferably from 1 μm to 8 μm.

In an alternate embodiment, to yield an ophthalmic lens the polymerizable composition is casted in a mould and the resulting light filtering material has a thickness ranging from 1 mm to 20 mm, preferably from 1 mm to 10 mm. After casting the light filtering material in a mould, curing and demoulding, a lens is obtained, whose optical surfaces have been defined by mould surfaces and whose optical properties results from composition of light filtering material.

Ophthalmic lenses should have specific optical properties. In particular, ophthalmic lenses must be transparent. By transparent, it is meant two properties. First, light scattering by ophthalmic lenses should be low, typically below 1% as measured with standard haze measurement according to ASTM D1003-00, preferably below 0.8%, even preferably below 0.5%. Second, the shape of an object seen throughout an ophthalmic lens should be unaltered, in the sense that the wearer of said ophthalmic lenses can recognize an object when looking through them. In this disclosure, transparency is not related to the absorbance of visible light. In other words, an ophthalmic lens may be transparent and coloured.

Matrix material suitable for manufacture of ophthalmic lenses have a refractive index about 1.5-1.74, preferably 1.5-1.56.

### Luminescent Semi-Conductive Nanoparticle

In an embodiment, semi-conductive nanoparticles are luminescent. When irradiated with high energy radiation, an exciton is formed in the nanoparticle, which eventually relax by emission of a photon of energy corresponding to the band-gap of semi-conductive nanoparticles. A glass container, a lens or a display comprising a luminescent semi-conductive nanoparticle may be authenticated by presence of a specific light emission.

### Uses Thereof

The present invention also relates to the use of a light filtering material according to the invention as a light filtering material on a glass container, on an optical substrate of ophthalmic lens, in a display such as for example in a screen.

### BRIEF DESCRIPTION OF THE DRAWINGS

FIG. 1 is a schematic representation of various shapes (spheres and plates) and structure (homostructure, core/shell, core/crown, dot in plate) of semi-conductive nanoparticles.

FIG. 2 shows the absorbance curves as a function of light wavelength (λ—in nm) of a first population of ZnSe nanospheres NP1 (dotted line), of a second population of ZnSe nanospheres NP2 (semi-dotted line), of a third population of ZnSe nanospheres NP3 (black solid line) and of a fourth population of ZnSe nanospheres NP4 (grey solid line).

FIG. 3 shows the absorbance curves as a function of light wavelength (λ—in nm) of CdS nanoplates in heptane (semi-dotted line), of CdS-MPA nanoparticles in water (dotted line) and of lens S1 comprising Diethylene glycol bis(allyl carbonate) and CdS nanoplates (solid line).

FIG. 4.1 shows the absorbance curves as a function of light wavelength (λ—in nm) of ZnSe nanospheres in toluene (semi-dotted line), of encapsulated ZnSe nanospheres in methanol (dotted line) and of lens S2 comprising a Sol-Gel coating comprising ZnSe nanospheres (solid line).

FIG. 4.2 shows the absorbance curves as a function of light wavelength (λ—in nm) of ZnSe nanoplates in toluene (semi-dotted line), of encapsulated ZnSe nanoplates in methanol (dotted line) and of lens S3 comprising a Sol-Gel coating comprising ZnSe nanoplates (solid line).

FIG. 5 shows transmission curves T of a comparative bottle B0 and a bottle B1 coated with a light filtering material according to this disclosure, as a function of light wavelength (λ—in nm).

FIG. 6 illustrates a structure of a display as disclosed herein.

FIG. 7 is a graph showing a chromaticity space CIE xy, with the gamut defined from three light sources: red (R), green (G) and blue (B) without light filtering material and with light filtering material (blue source is shifted from B to B′).

FIG. 8 shows intensity of white light (I—in arbitrary unit) emitted by a display as a function of light wavelength (λ—in nm) without light filtering material (L0) and with light filtering material L1.

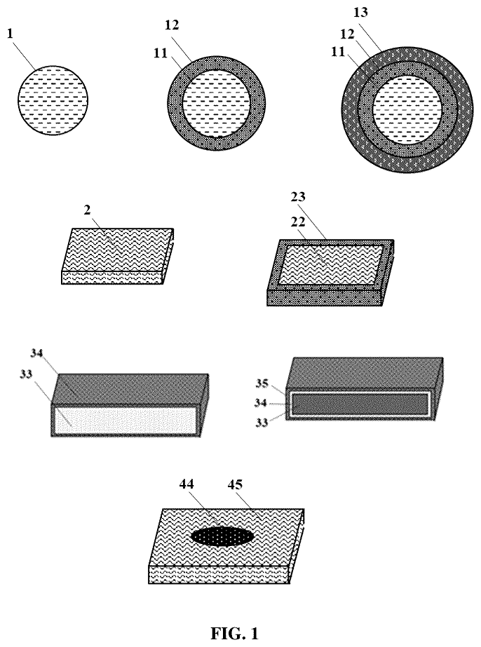

### EXAMPLES

The present invention is further illustrated by the following examples.

### Example 1a: Absorbance of Dispersion Comprising ZnSe Nanospheres

Semi-conductive nanoparticles of formula ZnSe (hereafter NP1) and having a shape of sphere with diameter of 5.4±0.2 nm were prepared according to procedure known by the man of the art and reported in New J. Chem., 2007, 31, 1843-1852. Specific purification steps included selective precipitation and redispersion in presence of organic ligands as alkylamines. A monodisperse population of ZnSe nanospheres (NP1) was obtained with a coefficient of variation inferior to 20%.

Similar experiment was conducted to synthesize ZnSe nanospheres, respectively with a diameter of 5.8±0.2 nm (NP2), 6.4±0.2 nm (NP3), 6.8±0.2 nm (NP4) and 7.4±0.2 nm (NP5). The same purification steps were used to obtain monodisperse populations of ZnSe nanospheres with a coefficient of variation inferior to 20%.

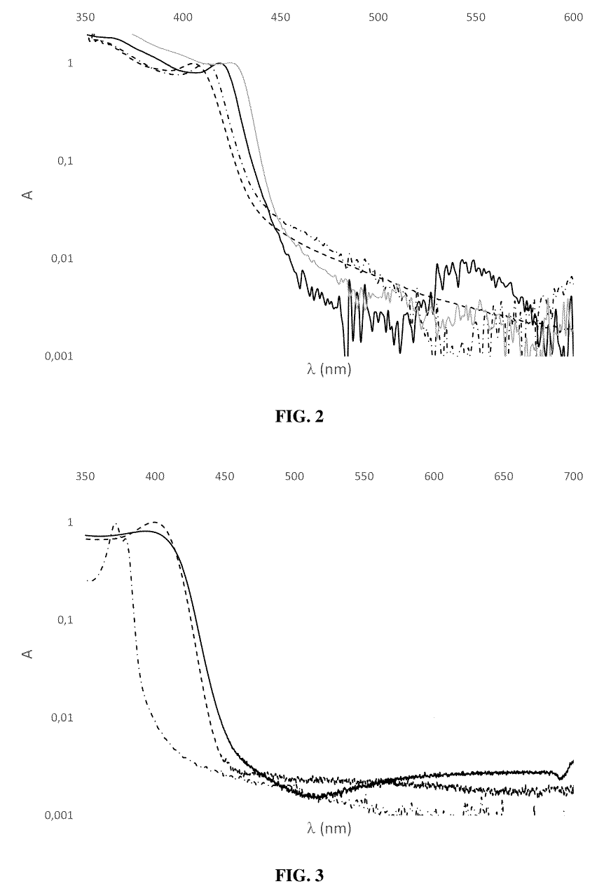

Absorbance curves of the first population of ZnSe nanospheres NP1 (dotted line), second population of ZnSe nanospheres NP2 (semi-dotted line), third population of ZnSe nanospheres NP3 (black line) and fourth population of ZnSe nanospheres NP4 (grey solid line) were measured as a function of light wavelength in the UV-visible and are shown on FIG. 2. Table 2 summarizes the results obtained for NP1-NP5.

An increase of λₘₐₓ value was observed when increasing the diameter of ZnSe nanospheres.

TABLE 2
Table 2: Results obtained for ZnSe populations NP1-NP5.

| | NP1 | NP2 | NP3 | NP4 | NP5 |
|---|---|---|---|---|---|
| diameter (nm) | 5.4 ± 0.2 | 5.8 ± 0.2 | 6.4 ± 0.2 | 6.8 ± 0.2 | 7.4 ± 0.2 |
| λₘₐₓ (nm) | 405 | 412 | 419 | 424 | 430 |
| λ(0.9*Aₘₐₓ) (nm) | 409 | 415 | 422 | 428 | 434 |
| λ(0.5*Aₘₐₓ) (nm) | 415 | 420 | 427 | 432 | 438 |
| λ(0.1*Aₘₐₓ) (nm) | 426 | 430 | 435 | 440 | 447 |
| \|λ_{0.5} − λ_{0.9}\| (nm) | 6 | 5 | 5 | 4 | 4 |
| \|λ_{0.1} − λ_{0.9}\| (nm) | 17 | 15 | 13 | 12 | 13 |

### Example 1b: Absorbance of CdSe Nanoparticles (Comparative)

Semi-conductive nanoparticles of formula CdSe and having a shape of plate with length of 10 nm; width of 20 nm and thickness of 1.2 nm (corresponding to 4 monolayers) were prepared according to procedure disclosed in EP2633102.

Table 3 summarizes the results obtained for CdSe nanoplates dispersion. The dispersion of CdSe nanoplates does not exhibit λₘₐₓ ranging from 350 to 500 nm.

TABLE 3
Table 3: Results obtained for CdSe nanoplates dispersion.

| | CdSe (4 monolayers | |
|---|---|---|
| λₘₐₓ | 512 | nm |
| λ(0.9*Aₘₐₓ) | 514 | nm |
| λ(0.5*Aₘₐₓ) | 516 | nm |
| λ(0.1*Aₘₐₓ) | 520 | nm |
| \|λ_{0.5} − λ_{0.9}\| | 2 | nm |
| \|λ_{0.1} − λ_{0.9}\| | 6 | nm |

### Example 2: Ophthalmic Lens Fabricated from a Polymerizable Composition Comprising Diethylene Glycol Bis(Allyl Carbonate) Monomer and CdS Nanoplates

Semi-conductive nanoparticles of formula CdS and having a shape of plate with length of 10 nm; width of 20 nm and thickness of 0.9 nm (corresponding to 3 monolayers) were prepared according to procedure disclosed in EP2633102.

5 mL of a dispersion comprising CdS nanoplates were mixed with 2 mL of 3-mercaptoproprionic acid (MPA). This mixture was heated at 60° C. for 2 hours. Nanoplates were recovered by centrifugation and washed three times with ethanol and toluene. CdS nanoplates capped with MPA were redispersed in water at pH=10. This dispersion is called dispersion D1. Dispersion D1 had a weight content in nanoparticles of 0.5%. Nanoparticles of dispersion D1 were encapsulated according to the procedure disclosed in EP3630683 within a silica shell.

Table 4 below discloses the absorbance of dispersion D1.

TABLE 4

| | | |
|---|---|---|
| λₘₐₓ | 400 | nm |
| λ_{0.9} (at 0.9*Aₘₐₓ) | 402 | nm |
| λ_{0.5} (0.5*Aₘₐₓ) | 406 | nm |
| λ_{0.1} (0.1*Aₘₐₓ) | 410 | nm |
| \|λ_{0.5} − λ_{0.9}\| | 4 | nm |
| \|λ_{0.1} − λ_{0.9}\| | 8 | nm |

10 mg of encapsulated CdS nanoplates of dispersion D1 were mixed with 1.65 mL of Diethylene glycol bis(allyl carbonate) and 100 mg of diisopropyl peroxydicarbonate (IPP) initiator. A homogeneous mixture is obtained by sonication in degassing mode at 25° C. for 60 seconds, yielding the polymerizable composition C1.

Polymerizable composition C1 was casted into moulds having centre thickness of 2 millimetres. The assembly was laid in an oven at 100° C. for 18 hours, then cooled and de-assembled, yielding plastic lens S1 of diameter about 2 cm.

Absorbance curves of CdS nanoplates in heptane (semi-dotted line), of CdS-MPA nanoparticles in water (dotted line) and of lens S1 (solid line) were measured as a function of light wavelength in the UV-visible and are shown on FIG. 3. A wavelength of transition λₘₐₓ of 399 nm is obtained for lens S1.

Besides, the characteristics of lens S1 for 20.9, 20.5 and 20.1 are the same as the characteristics of dispersion of nanoparticles listed in table 4: incorporation of nanoparticles into polymerizable composition didn't change absorbance features

Lens S1 is a transparent lens, i.e. there is no observable scattering and an object can be recognized when observed through the lens. However, these lenses absorb very efficiently high energy visible light with a very sharp transition in absorbance curve.

### Example 3: Ophthalmic Lens with Coatings Comprising ZnSe Nanospheres and Nanoplates

Semi-conductive nanoparticles of formula ZnSe and having a shape of sphere with diameter of 5.8±0.2 nm were prepared according to procedure known in the art and reported in New J. Chem., 2007, 31, 1843-1852.

5 mL of a dispersion comprising ZnSe nanospheres were mixed with 5 mL of 3-mercaptoproprionic acid (MPA). This mixture was heated at 60° C. for 2 hours. The nanospheres were recovered by centrifugation and washed three times with absolute ethanol and toluene. ZnSe nanospheres capped with MPA were redispersed in water at pH=10. These nanospheres were encapsulated according to the procedure disclosed in EP3630683 within a silica shell and redispersed in 0.5 mL of methanol. This dispersion was called dispersion D2 and had a weight content of 2.5% of nanospheres.

Table 5 below discloses the absorbance of dispersion D2.

TABLE 5

| | | |
|---|---|---|
| λₘₐₓ | 424 | nm |
| λ_{0.9} (at 0.9*Aₘₐₓ) | 428 | nm |
| λ_{0.5} (0.5*Aₘₐₓ) | 432 | nm |
| λ_{0.1} (0.1*Aₘₐₓ) | 440 | nm |
| \|λ_{0.5} − λ_{0.9}\| | 4 | nm |
| \|λ_{0.1} − λ_{0.9}\| | 12 | nm |

Same experiment was reproduced with semi-conductive nanoparticles of formula ZnSe and having a shape of nanoplates with thickness of 1.9 nm (corresponding to 5 monolayers), length of 15 nm and width of 30 nm. These nanoplates were prepared according to procedure known by the man of the art and reported in Mater. Lett. 2013, 99, 172-175. ZnSe nanoplates were capped with MPA and were redispersed in water at pH=10. These nanoplates were encapsulated according to the procedure disclosed in EP3630683 within a silica shell and redispersed in 0.5 mL of methanol. This dispersion was called dispersion D3 and had a weight content of 2.5% of nanoplates.

In addition, a Sol-Gel solution SG was also prepared in a separated vial with 100 μL of (3-Glycidyloxypropyl)trimethoxysilane, 65 μL of diethoxydimethylsilane and 35 μL of 0.1 M HCl. Solution SG was stirred for 24 hours at room temperature.

50 μL of dispersion D2 were added to 200 μL of solution SG to obtain a polymerizable composition then deposited by spin coating on a glass lens at 400 rpm during 30 s (dispensing step) then 2000 rpm during 2 min (spreading step). The resulting lens S2 was then heated at 150° C. for 6 h in order to obtain a condensed 5 μm thick Sol-Gel coating having a weight content in ZnSe nanospheres of 1% after curing.

Same experiment was reproduced with encapsulated ZnSe nanoplates. 50 μL of dispersion D3 were added to 200 μL of solution SG to obtain a polymerizable composition then deposited by spin coating on a glass lens at 400 rpm during 30 s (dispensing step) then 2000 rpm during 2 min (spreading step). The resulting lens S3 was then heated at 150° C. for 6 h in order to obtain a condensed 5 μm thick Sol-Gel coating having a weight content in ZnSe nanoplates of 1% after curing.

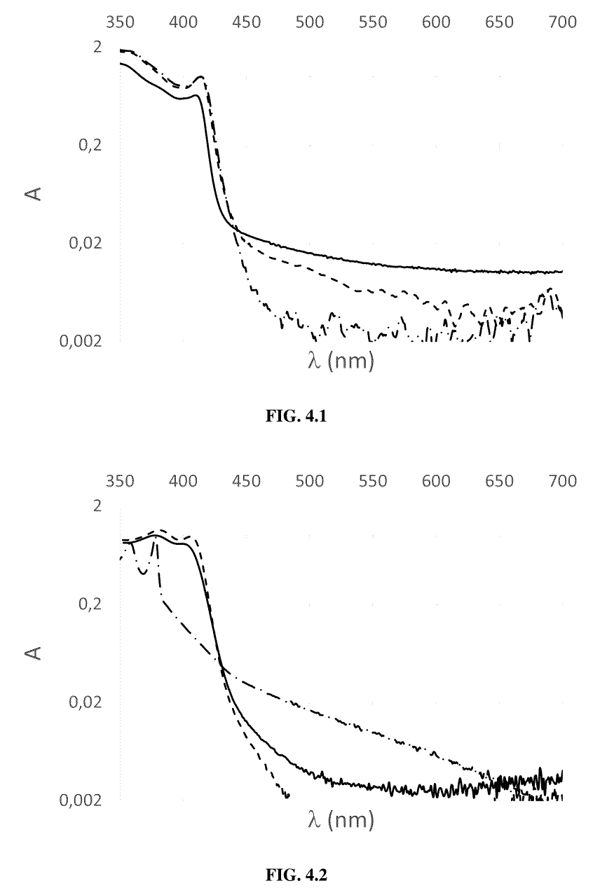

Absorbance curves of ZnSe nanospheres in toluene (semi-dotted line), of encapsulated ZnSe nanospheres in methanol (dotted line) and of the coated glass lens S2 (solid line) were measured as a function of light wavelength in the UV-visible and are shown on FIG. 4.1. A wavelength of transition λₘₐₓ of 410 nm is obtained for lens S2.

Besides, the characteristics of lens S2 for 20.9, 20.5 and 20.1 are the same as the characteristics of dispersion of nanoparticles listed in table 5: incorporation of nanoparticles in Sol-Gel coating didn't change absorbance features

Absorbance curves of ZnSe nanoplates in toluene (semi-dotted line), of encapsulated ZnSe nanoplates in methanol (dotted line) and of the coated glass lens S3 (solid line) were measured as a function of light wavelength in the UV-visible and are shown on FIG. 4.2. A wavelength of transition λₘₐₓ of 401 nm is obtained for lens S3.

### Example 4: Glass Container with a Light Filtering Material

All colorimetry measurements have been obtained after a measure of transmission followed by computation of colour. Transmission was measured with a JASCO UV-VIS770 spectrometer, with Xenon light source, for a range of wavelength from 380 nm to 780 nm. Spectrum of Illuminant D65 is defined in CIE standards.

Semi-conductive nanoparticles (hereafter NP6) of formula CdSe_{0.75}S_{0.25} and having a shape of plate with length of 12 nm; width of 20 nm and thickness of 1.2 nm (corresponding to 4 monolayers) were prepared according to procedure disclosed in EP2633102. Nanoparticles NP6 were capped with a Poly(DHLA-co-PEGMEMA) copolymer to respectively prepare dispersions D4.

A commercial glass bottle B0 was used as glass container. The color of B0 is measured in L*a*b* color system: L*=86.3; a*=−0.16 and b*=0.23. The commercial bottle B0 is dip-coated with dispersions D4, then heated at 150° C. for 6 h in order to obtain a condensed 5 μm thick Sol-Gel coating having a weight content in nanoparticles NP6 of 1% after curing. Resulting coated bottle is B1.

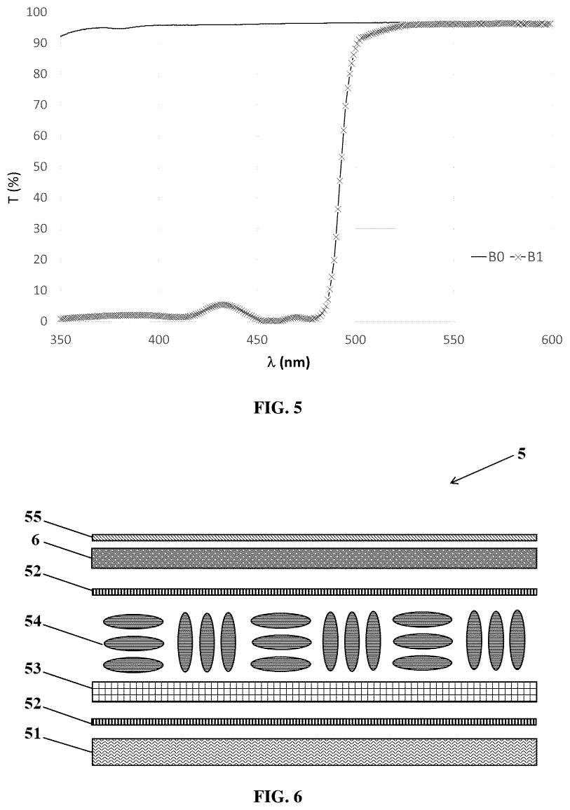

FIG. 5 shows light transmission through bottles B0 as a control and B1. Aₘₐₓ for bottle B1 is 480 nm.

A solution of Riboflavin at concentration of 250 mg·L⁻¹ is prepared. This solution when measured in a 1 cm path light cuvette presents a maximum of absorbance at 442 nm with absorbance 1.03.

Bottle B0 was filled with the solution of Riboflavin and exposed to blue LED light exposure for 30 hours (emission spectrum of LED 430-465 nm, irradiance 0.1 W/cm²). Absorbance curves were recorded at different duration of blue light exposure for 0, 1, 4, 7, 12, 15, 24 and 30 hours. Absorbance at 442 nm is decreasing from 1.03 to 0.124 demonstrating that 88% Riboflavin has been photodegraded after 30 hours of blue light exposure.

The same experiment was reproduced using bottle B1. As a control, the same measurement was done in a bottle B0, without light exposure.

Table 6 below shows Riboflavine degradation and colorimetric properties of the bottles.

TABLE 6

| | λₘₐₓ | | Lightness | | | Luminous |
|---|---|---|---|---|---|---|
| Bottle | (nm) | % degradation | (variation from B0) | | Chroma | transmission |
| B0 | NA | 88 | 86.3 | | 0.3 | >95% |
| B1 | 480 | 13 | 84.5 | (−1.8) | 60 | >95% |
| B0 - No light | NA | <2% | 86.3 | (0) | 0.3 | NA |

Table 6 demonstrates that degradation of Riboflavin contained in bottle B1 has been prevented thanks to light filtering material.

Lightness of glass bottle B1 is almost unchanged (from 86.3 to 84.5) and chroma is 60.

Finally, bottle B1 is a good light filtering glass container, providing protection against development of lightstruck flavour in beverages without degrading brightness of the glass container.

### Example 5: Display Comprising a Light Filtering Material

5 mL of a dispersion comprising ZnSe nanospheres NP5 were mixed with 5 mL of 3-mercaptoproprionic acid (MPA). This mixture was heated at 60° C. for 2 hours and then washed three times with absolute ethanol and toluene. ZnSe nanoparticles capped with MPA were redispersed in water at pH=10. These nanospheres were encapsulated according to the procedure disclosed in EP3630683 within a silica shell and redispersed in 0.5 mL of methanol. This dispersion D4 had a weight content of 2.5% of nanospheres.

In addition, a Sol-Gel solution SG was also prepared in a separated vial with 100 μL of (3-Glycidyloxypropyl) trimethoxysilane, 65 μL of diethoxydimethylsilane and 35 μL of 0.1 M HCl. Solution SG was stirred for 24 hours at room temperature.

50 μL of dispersion D4 were added to 200 μL of solution SG to obtain a polymerizable composition then deposited by spin coating on a glass protective layer of a standard LCD display at 400 rpm during 30 s (dispensing step) then 2000 rpm during 2 min (spreading step). The resulting layer L1 was then heated at 150° C. for 6 h in order to obtain a condensed 5 μm thick Sol-Gel coating having a weight content in ZnSe nanospheres of 1% after curing. Thickness of layer L1 was adjusted to have an absorbance equal to 1 at λmax.

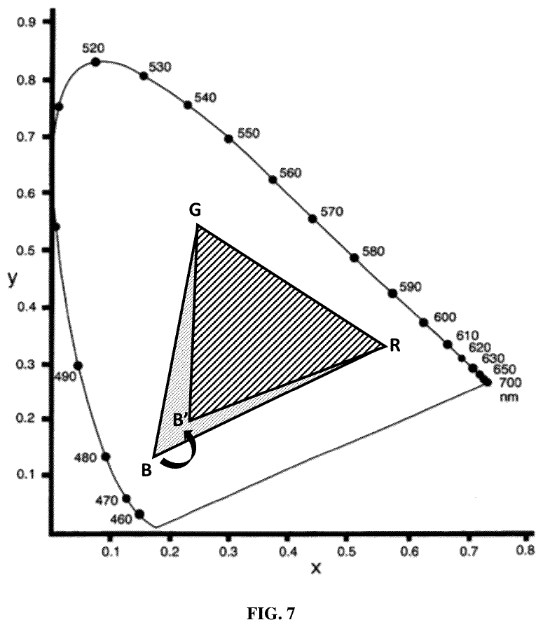

Layer L1 (6) was coated on the inner side of glass protective layer (55) and disposed in a display with a configuration shown on FIG. 6. In this display, light sources of image producing system comprises blue LED.

High energy blue light emitted by blue LED was very efficiently filtered out with layer L1 as the amount of light having a wavelength below 440 nm was dramatically decreased.

Table 7 below shows the amount of light filtered out for range of wavelength 400-440 nm (light to be filtered out) and range 440-500 nm (light to be maintained). Table 7 also shows the wavelength of maximum emission (nm). The characteristics of layer L1 for Aₘₐₓ, λ_{0.9}, λ_{0.5} and λ_{0.1} are the same as the characteristics of dispersion of nanoparticles listed in table 2: incorporation of nanoparticles in Sol-Gel coating didn't change absorbance features.

TABLE 7

| | 400-440 nm (%) | 440-500 nm (%) | Peak (nm) |
|---|---|---|---|
| Layer L1 | 87 | 13.6 | 447 |

Layer L1 is a good compromise to filter out high energy blue light without changing too much the emission peak of blue light, in particular the wavelength of maximum emission is not shifted and remains at 454 nm.

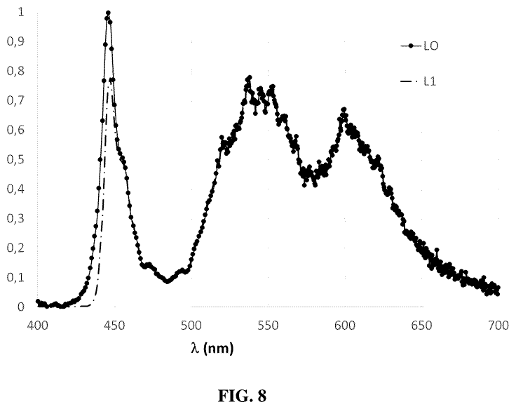

In this display, fluorescent materials are used to produce green and red light, from blue light emitted by blue LED. FIG. 8 shows intensity of white light emitted by display (I—in arbitrary unit) as a function of light wavelength (λ—in nm) without light filtering material (L0) and with light filtering material L1.

Table 8 below shows coordinates of red, green, blue and white light emitted by this display, without light filtering material (L0) and with light filtering material L1, in the CIE Luv colour space. Taking for display without filter gamut G₀ equal to 100, the gamut G₁ of display with filter is 95.1.

TABLE 8

| | No filter | Filter L1 |
|---|---|---|
| Blue | (0.15-0.05) | (0.15-0.06) |
| Green | (0.31-0.63) | (0.31-0.63) |
| Red | (0.65-0.35) | (0.65-0.35) |
| White point | (0.33-0.33) | (0.35-0.41) |

In the CIE xyY color space, taking for display without filter gamut G₀ equal to 100, the gamut G₁ of display with filter is 97.4.

With filter L1, colour of white light has been slightly changed. However, colour of white light in such displays is defined by intensity of the three sources (red, green and blue). It is thus straightforward to increase intensity of blue source to restore a white light with coordinates of (0.33, 0.33) in CIE Luv. This adjustment has no effect on gamut.

Finally, filtering layer L1 demonstrates a very efficient compromise: emission of high energy blue light by display is strongly limited and ability to produce colours over a wide range is maintained.

1-15. (canceled)

16. A light filtering material comprising:
a) at least one matrix material; and
b) semi-conductive nanoparticles which are dispersed in said matrix material; and
wherein said light filtering material absorbs light, and
wherein absorbance of said light filtering material has:
a local maximum absorbance of highest wavelength in the range from 350 to 500 nm, said local maximum having an absorbance value Aₘₐₓ for a wavelength λₘₐₓ,
a value of 0.9Aₘₐₓ for a wavelength λ_{0.9}, λ_{0.9} being greater than λₘₐₓ;
a value of 0.5Aₘₐₓ for a wavelength λ_{0.5}, λ_{0.5} being greater than λ_{0.9}; and
wherein |λ_{0.5}−λ_{0.9}| is less than 15 nm.

17. The light filtering material according to claim 16, wherein absorbance of said light filtering material has a value of 0.1Aₘₐₓ for a wavelength λ_{0.1}, λ_{0.1} being greater than λ_{0.9}; and wherein |λ_{0.1}−λ_{0.9}| is less than 30 nm.

18. The light filtering material according to claim 16, wherein the semi-conductive nanoparticles comprise a material of formula
MₓQ_{y}E_{z}A_{w} (I),
wherein:
M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs or a mixture thereof;
E is selected from the group consisting of O, S, Se, Te, C, N, P, As, Sb, F, Cl, Br, I, or a mixture thereof;
A is selected from the group consisting of O, S, Se, Te, C, N, P, As, Sb, F, Cl, Br, I, or a mixture thereof; and
x, y, z and w are independently a decimal number from 0 to 5; x, y, z and w are not simultaneously equal to 0; x and y are not simultaneously equal to 0; z and w may not be simultaneously equal to 0.

19. The light filtering material according to claim 16, wherein the semi-conductive nanoparticles are nanospheres, nanoplates or nanorods.

20. The light filtering material according to claim 16, wherein the semi-conductive nanoparticles are homostructures.

21. The light filtering material according to claim 16, wherein the semi-conductive nanoparticles are core/shell nanoparticles or core/crown nanoparticles, the core being a different material from the shell or crown.

22. The light filtering material according to claim 16, wherein the amount of semi-conductive nanoparticles in the light filtering is from 10 ppm to 10 wt %, based on the weight of the light filtering material.

23. The light filtering material according to claim 16, wherein the semi-conductive nanoparticles are capped with an organic layer, an inorganic layer or a mixture thereof, and/or encapsulated in an inorganic matrix.

24. The light filtering material according to claim 16, wherein the matrix material is an organic material or an inorganic material.

25. The light filtering material according to claim 24, wherein the organic material is selected from allyl polymers, (meth)acrylic polymers; epoxy compounds; polyurethane, polythiourethane materials, or mixture thereof.

26. The light filtering material according to claim 24, wherein the inorganic material is selected from sol gel materials, mineral oxides, or mixture thereof.

27. A display comprising an image producing system and a light filtering material according to claim 16.

28. A light filtering glass container comprising glass container partially or totally coated with the light filtering material according to claim 16.

29. An ophthalmic lens comprising the light filtering material according to claim 16.
